(19) United States
(12) Patent Application Publication
(10) Pub. No.: US 2026/0182056 A1
(43) Pub. Date: Jun. 25, 2026

(54) IMAGE SENSOR

(71) Applicant: SAMSUNG ELECTRONICS CO., LTD., Suwon-si (KR)

(72) Inventors: WONHYEOK KIM, Suwon-si (KR); Youngseo KIM, Suwon-si (KR); UISIK KIM, Suwon-si (KR); ILJOONG KIM, Suwon-si (KR)

(73) Assignee: SAMSUNG ELECTRONICS CO., LTD., Suwon-si (KR)

(21) Appl. No.: 19/421,899

(22) Filed: Dec. 16, 2025

(30) Foreign Application Priority Data
Dec. 23, 2024 (KR) 10-2024-0194687
Jan. 23, 2025 (KR) 10-2025-0010617

(51) Int. Cl. H10F 39/00

(52) U.S. Cl. CPC H10F 39/8053; H10F 39/8027; H10F 39/8063

(57) ABSTRACT

An image sensor includes a substrate comprising a first surface, a second surface opposing the first surface, a first region located at a center area of the substrate, an optical black region, and a second region between the first region and the optical black region in a plan view, a plurality of color filters on the second surface of the substrate, a first grid between the plurality of color filters on the first region, and a second grid between the plurality of color filters on the second region. The first grid may include N layers stacked in a first direction perpendicular to the second surface of the substrate, the second grid may include M layers stacked in the first direction, a height of the first gird in the first direction may be different from a height of the second grid in the first direction, the N and M may be integers equal to or greater than 1, the N may be different from the M, and the image sensor may be configured to receive light from the second surface of the substrate.

### CROSS-REFERENCE TO RELATED APPLICATION(S)

The application claims priority under 35 U.S.C. § 119 to Korean Patent Application No. 10-2024-0194687 filed on Dec. 23, 2024, and Korean Patent Application No. 10-2025-0010617 filed on Jan. 23, 2025, in the Korean Intellectual Property Office, the disclosures of which are incorporated by reference herein in their entireties.

### BACKGROUND

Embodiments of the present disclosure relate to an image sensor.

An image sensor is a device converting optical image signals into electrical signals. Image sensors include charge-coupled device (CCD) image sensors and complementary metal-oxide semiconductor (CMOS) image sensors. An image sensor includes a plurality of pixels. Each of the plurality of pixels may include a photoelectric conversion region that receives incident light and converts the received light into an electrical signal, and a pixel circuit that outputs a pixel signal using the charge generated in the photoelectric conversion region. Image sensors are used in various fields, such as digital cameras, camcorders, smartphones, gaming devices, surveillance cameras, medical micro-cameras, robots, and vehicles.

### SUMMARY

Embodiments of the present disclosure provide an image sensor having improved optical characteristics. However, embodiments are not limited thereto.

According to one or more embodiments, an image sensor includes a substrate comprising a first surface, a second surface opposing the first surface, a first region located at a center area of the substrate, an optical black region, and a second region between the first region and the optical black region in a plan view, a plurality of color filters on the second surface of the substrate, a first grid between the plurality of color filters on the first region, and a second grid between the plurality of color filters on the second region. The first grid may include N layers stacked in a first direction perpendicular to the second surface of the substrate, the second grid may include M layers stacked in the first direction, a height of the first gird in the first direction may be different from a height of the second grid in the first direction, the N and M may be integers equal to or greater than 1, the N may be different from the M, and the image sensor may be configured to receive light from the second surface of the substrate.

According to one or more embodiments, an image sensor includes a substrate including a first surface, a second surface opposing the first surface, a first region located at a center area of the substrate, an optical black region, and a second region between the first region and the optical black region in a plan view, a plurality of color filters on the second surface of the substrate, a first grid between the plurality of color filters on the first region, a second grid between the plurality of color filters on the second region, and a third grid on the second surface of the substrate on the optical black region. The first grid may include N layers stacked in a first direction perpendicular to the second surface of the substrate, the second grid may include M layers stacked in the first direction, the third grid may include L layers stacked in the first direction, a height of the first gird in the first direction may be smaller than a height of the second grid in the first direction, the height of the first gird in the first direction may be smaller than and a height of the third grid in the first direction, the N, M, and L may be integers equal to or greater than 1, the M may be greater than the N, the L may be greater than the N, and the image sensor may be configured to receive light from the second surface of the substrate.

According to one or more embodiments, an image sensor includes a substrate including a first surface, a second surface opposing the first surface, a first region located at a center area of the substrate, an optical black region, and a second region between the first region and the optical black region in a plan view, a plurality of color filters on the second surface of the substrate, a first grid between the plurality of color filters on the first region, a second grid between the plurality of color filters on the second region, a first microlens on a first photodiode and a second photodiode on the first region, and a second microlens on a third photodiode and a fourth photodiode on the second region. The first grid may include N layers stacked in a first direction perpendicular to the second surface of the substrate, the second grid may include M layers stacked in the first direction, a height of the first gird in the first direction may be smaller than a height of the second grid in the first direction, the N and M may be integers equal to or greater than 1, the N may be different from the M, the first gird may not be disposed at a center of the first microlens in a vertical view, the second gird may not be disposed at a center of the second microlens in a vertical view, and the image sensor may be configured to receive light from the second surface of the substrate.

### BRIEF DESCRIPTION OF DRAWINGS

FIG. 1 is a plan view illustrating a pixel region of an image sensor according to one or more embodiments.

FIG. 2 is a plan view illustrating pixels in FIG. 1, according to one or more embodiments.

FIG. 3A is a cross-sectional view illustrating the pixels on a first region in FIG. 1, taken along line B1-B1′ of FIG. 2.

FIG. 3B is a cross-sectional view illustrating the pixels on a first region in FIG. 1, taken along line B2-B2′ of FIG. 2.

FIG. 4A is an enlarged cross-sectional view of a transfer gate structure.

FIG. 4B is an enlarged cross-sectional view of a pixel gate structure.

FIG. 4C is an enlarged cross-sectional view of a second insulating layer.

FIG. 5A is a cross-sectional view illustrating pixels on an intermediate region of FIG. 1, taken along line B1-B1′ of FIG. 2.

FIG. 5B is a cross-sectional view illustrating pixels on an intermediate region of FIG. 1, taken along line B2-B2′ of FIG. 2.

FIG. 6A is a cross-sectional view illustrating pixels on a second region of FIG. 1, taken along line B1-B1′ of FIG. 2.

FIG. 6B is a cross-sectional view illustrating pixels on a second region of FIG. 1, taken along line B2-B2′ of FIG. 2.

FIG. 7A is a cross-sectional view illustrating dummy pixels on a third region of FIG. 1, taken along line B1-B1′ of FIG. 2.

FIG. 7B is a cross-sectional view illustrating dummy pixels on a third region of FIG. 1, taken along line B2-B2′ of FIG. 2.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, or as “contacting” or “in contact with” another element (or using any form of the word “contact”), there are no intervening elements or layers present.

Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

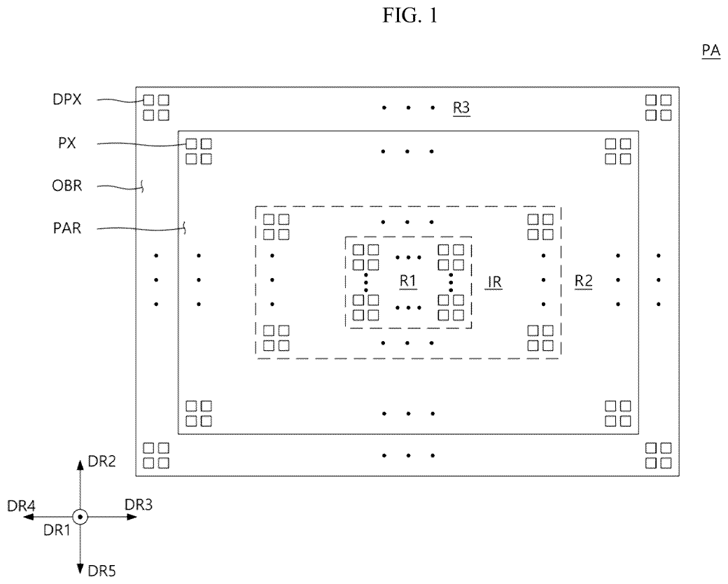

FIG. 1 is a plan view illustrating a pixel region of an image sensor according to one or more embodiments.

The pixel region PA may include a pixel array region PAR and an optical black region OBR. The optical black region OBR may be disposed at an edge of the pixel region PA to surround the pixel array region PAR. In one or more embodiments, the pixel array region PAR may be an active pixel sensor region, and the optical black region OBR may be an optical black pixel region.

The pixel array region PAR may include a first region R1, an intermediate region IR, and a second region R2. The optical black region OBR may include a third region R3. The first region R1 may be located at a center of the pixel array region PAR. The intermediate region IR may surround the first region R1 in a plan view. The second region R2 may surround the intermediate region IR in a plan view. The optical black region OBR may surround the second region R2 in a plan view. For example, the second region R2 may be provided between the first region R1 and the optical black region OBR in a plan view. The second region R2 may be disposed adjacent to the optical black region OBR in a plan view. In some embodiments, the intermediate region IR may be provided in a plurality. For example, the intermediate region IR may include two or more intermediate regions. Alternatively, the intermediate region may be omitted in some embodiments.

The pixel array region PAR may include a plurality of pixels PX arranged two-dimensionally. The plurality of pixels PX may convert an optical signal into an electrical signal. The plurality of pixels PX may be arranged in a specific pattern to generate a high-quality image. In one or more embodiments, the plurality of pixels PX may be arranged in a Bayer pattern or a chess mosaic pattern. For example, each of the plurality of pixels PX may be configured to receive red light, green light, or blue light.

In one or more embodiments, the plurality of pixels PX may be grouped into a plurality of pixel groups arranged two-dimensionally. For example, a single pixel group among the plurality of pixel groups may include four pixels PX arranged in a 2×2 form. Alternatively, the single pixel group may include four pixels PX arranged in a 1×4 form. Alternatively, the single pixel group may include eight pixels PX arranged in a 1×4 form. However, embodiments are not limited thereto. The arrangement of the respective pixels PX of the pixel groups according to one or more embodiments may be variously designed based on required optical characteristics.

For example, the pixels PX included in the same pixel group, among the plurality of pixels PX, may be configured to receive light of the same color, and may be disposed below the same color filter. The plurality of pixel groups may be arranged in a specific pattern to generate a high-quality image. In one or more embodiments, the plurality of pixel groups may be arranged in a Bayer pattern or a chess mosaic pattern. For example, each of the plurality of pixel groups may include a plurality of pixels PX configured to receive red light, green light, or blue light.

The optical black region OBR may include a plurality of dummy pixels DPX arranged two-dimensionally. The plurality of dummy pixels DPX may be configured not to receive incident light. For example, the image sensor may include a light blocking element, such as a light blocking layer, configured to prevent incident light from reaching the plurality of dummy pixels DPX. In one or more embodiments, the plurality of dummy pixels DPX may be formed in the same process step as the plurality of pixels PX.

Each of the plurality of pixels PX may include a photodiode PD (for example, a photoelectric conversion element). The photodiode PD may absorb light and generate charge carriers e.g., electrons or holes. As described above, the photodiode PD may include one or more photodiodes, phototransistors, photogates, or pinned photodiodes. An output voltage of the plurality of pixels PX may be determined based on the generated charge carriers.

In one or more embodiments, although not illustrated, adjacent pixels PX among the plurality of pixels PX may be configured to share a reset transistor RX, a select transistor SEL, and a source follower transistor SF.

Each of the plurality of pixels may include a photodiode PD and at least one gate terminal of a transfer transistor TX. The photodiode PD may generate and accumulate photocharges in proportion to an amount of light incident from the outside. The photodiode PD may include a phototransistor, a photogate, a pinned photodiode, or combinations thereof.

The transfer transistor TX may include the gate terminal. The gate terminal may be provided between the photodiode PD and a floating diffusion region FD. The gate terminal may be configured to transfer the generated photocharges within the photodiode PD to the floating diffusion region FD based on a transfer control voltage applied to the gate terminal.

The floating diffusion region FD may receive the photocharges generated in the photodiode PD, accumulate the photocharges, and store the photocharges. A source follower transistor SF may be controlled based on the amount of charges accumulated in the floating diffusion region FD. A gate terminal of the source follower transistor SF may be electrically connected to the floating diffusion region FD. A source terminal of the source follower transistor SF may be electrically connected to a drain terminal of the select transistor SEL. The source follower transistor SF may be a source follower buffer amplifier outputting a current in proportion to the amount of the accumulated charges of the floating diffusion region FD. The reset transistor RX may periodically reset the accumulated charges in the floating diffusion region FD.

The select transistor SEL may select a portion of the plurality of pixels PX in a row unit. The select transistor SEL may transfer a current, generated in the source follower transistor SF electrically connected to each of the portion of pixels PX, to an output line.

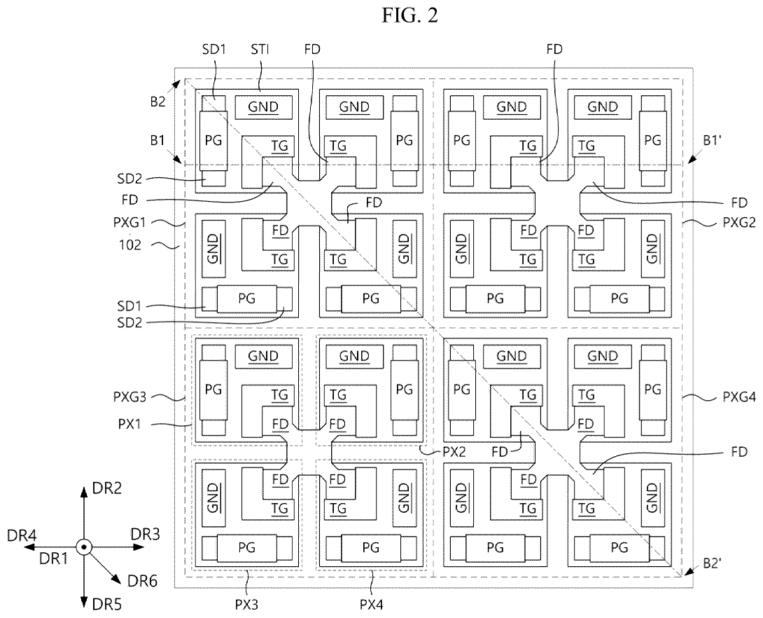

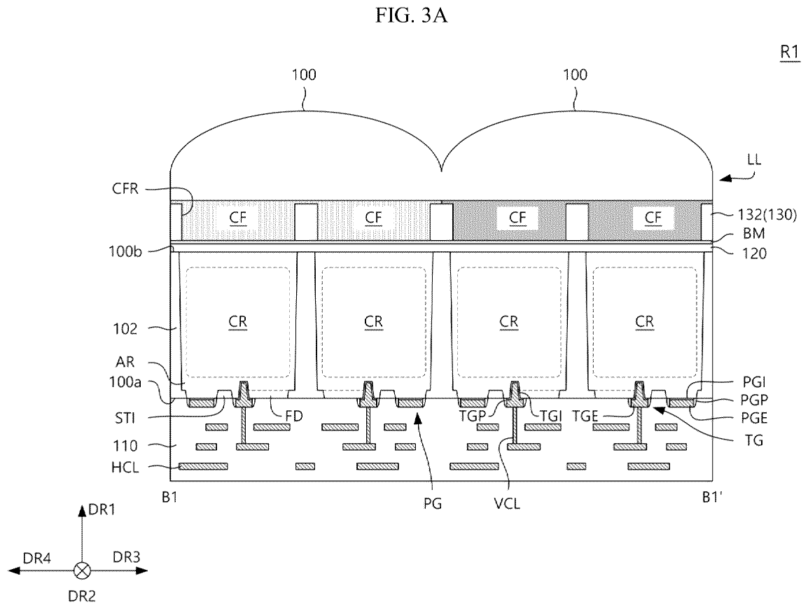

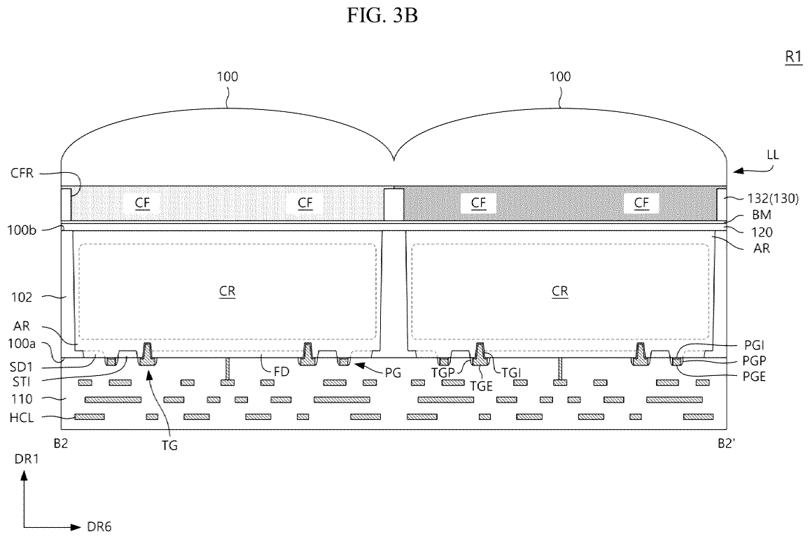

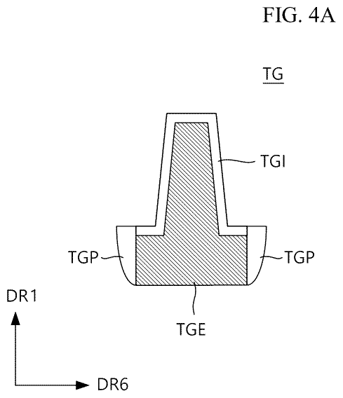

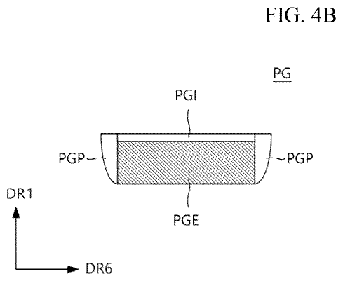

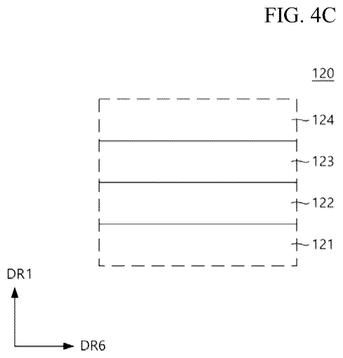

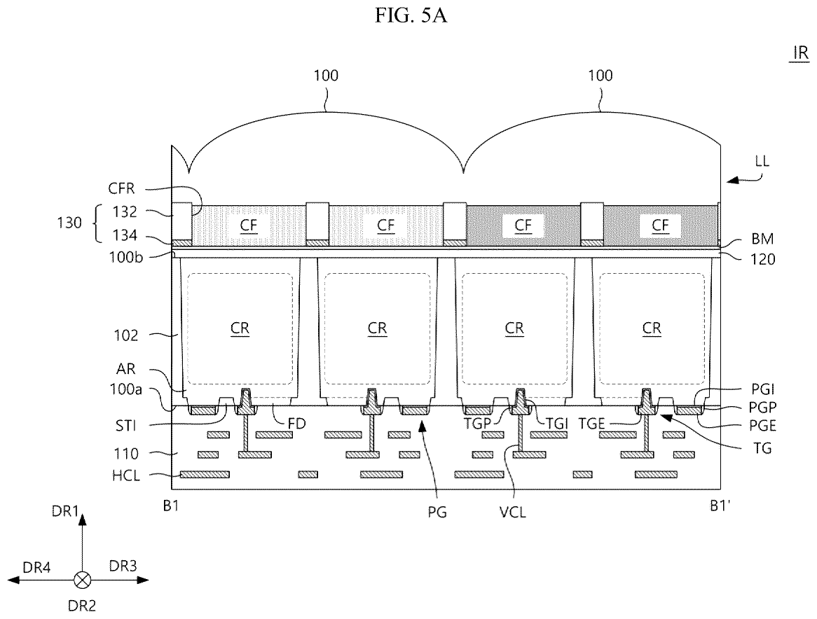

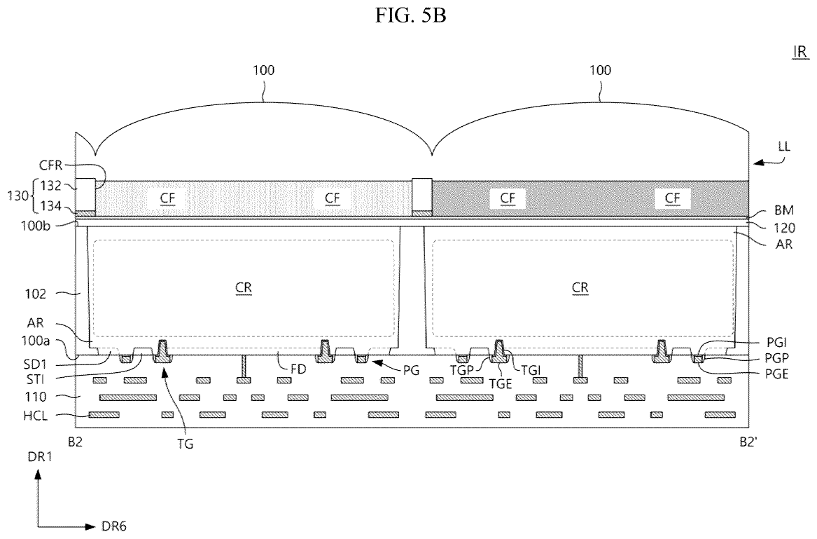

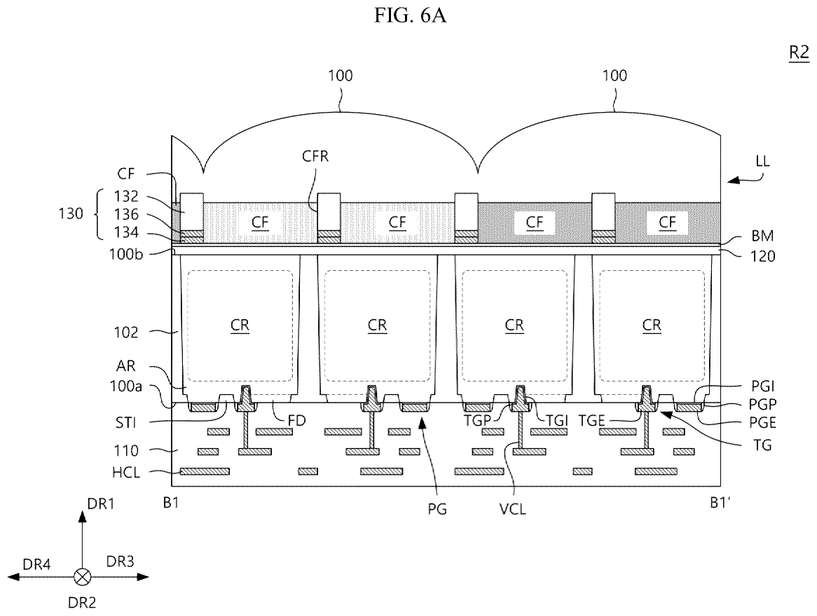

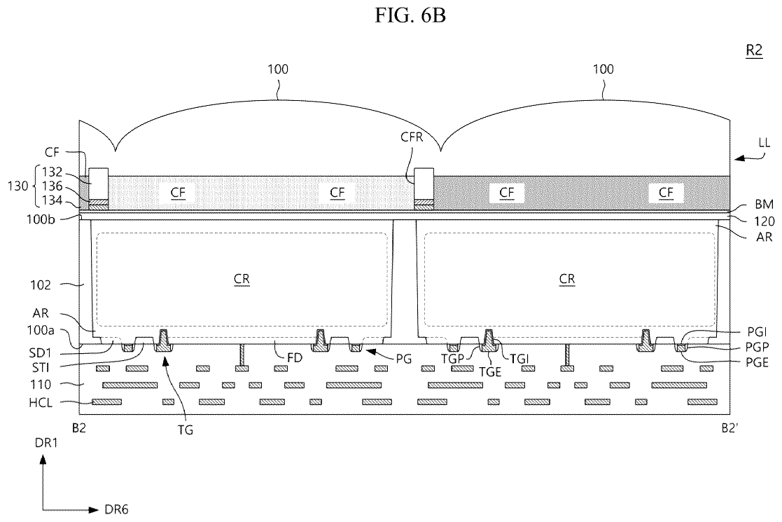

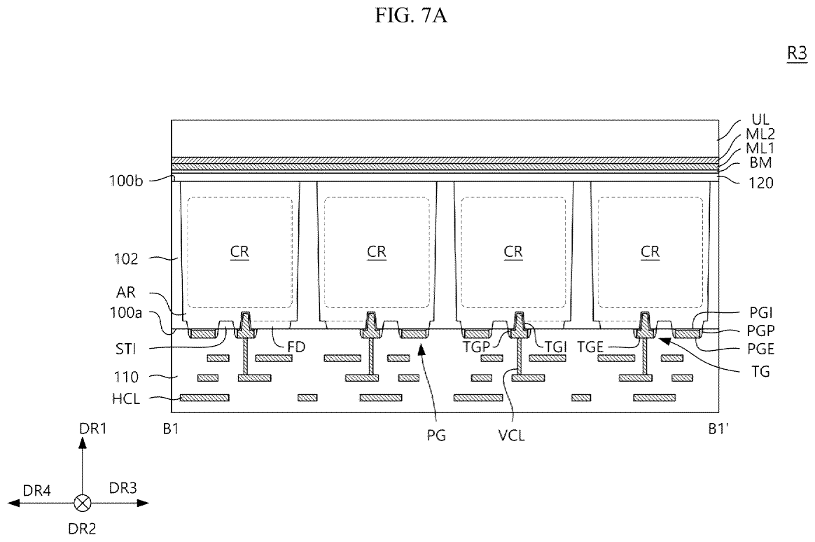

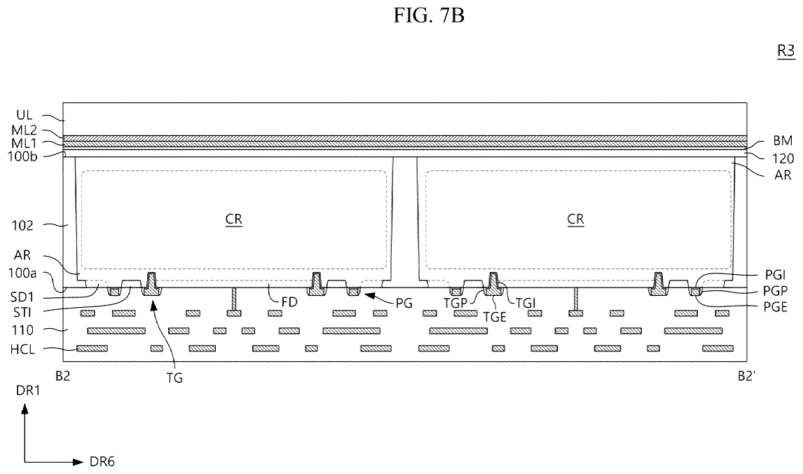

FIG. 2 is a plan view illustrating pixels in FIG. 1, according to one or more embodiments. FIG. 3A is a cross-sectional view illustrating the pixels on a first region in FIG. 1, taken along line B1-B1′ of FIG. 2. FIG. 3B is a cross-sectional view illustrating the pixels on a first region in FIG. 1, taken along line B2-B2′ of FIG. 2. FIG. 4A is an enlarged cross-sectional view of a transfer gate structure, FIG. 4B is an enlarged cross-sectional view of a pixel gate structure, and FIG. 4C is an enlarged cross-sectional view of a second insulating layer. FIG. 5A is a cross-sectional view illustrating pixels on an intermediate region of FIG. 1, taken along line B1-B1′ of FIG. 2, and FIG. 5B is a cross-sectional view illustrating pixels on an intermediate region of FIG. 1, taken along line B2-B2′ of FIG. 2. FIG. 6A is a cross-sectional view illustrating pixels on a second region of FIG. 1, taken along line B1-B1′ of FIG. 2, and FIG. 6B is a cross-sectional view illustrating pixels on a second region of FIG. 1, taken along line B2-B2′ of FIG. 2. FIG. 7A is a cross-sectional view illustrating dummy pixels on a third region of FIG. 1, taken along line B1-B1′ of FIG. 2, and FIG. 7B is a cross-sectional view illustrating dummy pixels on a third region of FIG. 1, taken along line B2-B2′ of FIG. 2.

Referring to FIGS. 2, 3A, 3B, 4A, 4B, 4C, and 5A to 7B, a substrate 100 may be provided. The substrate 100 may have a first surface 100a and a second surface 100b opposing the first surface 100a. A first direction DR1 may be perpendicular to the first surface 100a and the second surface 100b of the substrate 100. The first surface 100a and the second surface 100b may extend in a second direction DR2 and a third direction DR3. The first surface 100a and the second surface 100b may be spaced apart from each other in the first direction DR1. The second direction DR2 may be parallel to the first surface 100a. The third direction DR3 may be parallel to the first surface 100a, and the third direction DR3 may intersect the second direction DR2. The first direction DR1 may be perpendicular to the second direction DR2 and the third direction DR3.

The substrate 100 may be a semiconductor substrate. For example, the substrate 100 may include silicon (Si), germanium (Ge), or silicon-germanium (SiGe). The substrate 100 may have a first conductivity type. For example, the first conductivity type may be a P-type or an N-type. For example, when a conductivity type of the substrate 100 is the P-type, the substrate 100 may include a group 3 element (for example, boron (B), aluminum (Al), gallium (Ga), indium (In), or the like) or a group 2 element as an impurity. Hereinafter, a region having the P-type conductivity type may include a group 3 or group 2 element as an impurity. For example, when a conductivity type of the substrate 100 is the N-type, the substrate 100 may include an impurity of a group 5 element (for example, phosphorus (P), arsenic (As), antimony (Sb), or the like), a group 6 element, or a group 7 element. Hereinafter, a region having the N-type conductivity type may include a group 5, group 6, or group 7 element as an impurity. The second conductivity type may be opposite to the first conductivity type. For example, when the first conductivity type is the P-type, the second conductivity type may be the N-type. Alternatively, when the first conductivity type is the N-type, the second conductivity type may be the P-type.

The substrate 100 may be an epitaxial layer formed by an epitaxial growth process.

The substrate 100 may include the first region R1, the intermediate region IR, and the second and third regions R2 and R3. The third region R3 may be the optical black region OBR described above with reference to FIG. 1.

In one or more embodiments, each of the first region R1, the intermediate region IR, and the second and third regions R2 and R3 may include a first pixel group PXG1, a second pixel group PXG2, a third pixel group PXG3, and a fourth pixel group PXG4. Each of the first to fourth pixel groups PXG1, PXG2, PXG3, PXG4 may be defined by a photodiode isolation pattern 102.

The first and second pixel groups PXG1 and PXG2 may be arranged in the third direction DR3. Referring to FIG. 2, the second pixel group PXG2 may be symmetrical to the first pixel group PXG1 with respect to an axis extending in the second direction DR2 provided between the first pixel group PXG1 and the second pixel group PXG2. The first and third pixel groups PXG1 and PXG3 may be arranged in the second direction DR2. Referring to FIG. 2, the third pixel group PXG3 may have substantially the same shape as the first pixel group PXG1 rotated by 90 degrees counterclockwise. The third and fourth pixel groups PXG3 and PXG4 may be arranged in the third direction DR3. Referring to FIG. 2, the fourth pixel group PXG4 may have substantially the same shape as the second pixel group PXG2 rotated by 90 degrees clockwise.

Each of the first to fourth pixel groups PXG1, PXG2, PXG3, and PXG4 may include a first pixel PX1, a second pixel PX2, a third pixel PX3, and a fourth pixel PX4. Each of the first to fourth pixels PX1, PX2, PX3, and PX4 may be defined by the photodiode isolation pattern 102.

The first and second pixels PX1 and PX2 may be arranged in the third direction DR3. Referring to FIG. 2, the second pixel PX2 may be symmetrical to the first pixel PX1 with respect to an axis extending in the second direction DR2 provided between the first pixel PX1 and the second pixel PX2. The first and third pixels PX1 and PX3 may be arranged in the second direction DR2. Referring to FIG. 2, the third pixel PX3 may have substantially the same shape as the first pixel PX1 rotated by 90 degrees counterclockwise. The third and fourth pixels PX3 and PX4 may be arranged in the third direction DR3. Referring to FIG. 2, the fourth pixel PX4 may have substantially the same shape as the second pixel PX2 rotated by 90 degrees clockwise.

Each of the first to fourth pixels PX1, PX2, PX3, and PX4 may include a photodiode region AR. The photodiode region AR of each of the first to fourth pixels PX1, PX2, PX3, and PX4 in the third region R3 may be a dummy photodiode region. Photoelectric conversion regions CR may be provided in the photodiode regions AR, respectively.

In one or more embodiments, each of the photoelectric conversion regions CR may include at least one photodiode. For example, the first region R1 may include a first photodiode (which may be referred to as a first first-region photodiode in the present specification) and a second photodiode (which may be referred to as a second first-region photodiode in the present specification), and the second region R2 may include a third photodiode (which may be referred to as a first second-region photodiode in the present specification) and a fourth photodiode (which may be referred to as a second second-region photodiode in the present specification).

In one or more embodiments, each of the first to fourth pixel groups PXG1, PXG2, PXG3, and PXG4 may include four photodiodes arranged in a 2 x2 matrix in a plan view. In the present specification, the four photodiodes of the first pixel group PXG1 of the first region R1 may be referred to as first-four photodiodes, the four photodiodes of the second pixel group PXG2 of the first region R1 may be referred to as second-four photodiodes, the four photodiodes of the third pixel group PXG3 of the first region R1 may be referred to as third-four photodiodes, and the four photodiodes of the fourth pixel group PXG4 of the first region R1 may be referred to as fourth-four photodiodes.

For example, each of the photoelectric conversion regions CR may include a PN photodiode. The PN photodiode may include a PN junction. Each of the photoelectric conversion regions CR may include a P-type region and an N-type region. The substrate 100 may have the first conductivity type. For example, the first conductivity type may be the P-type. When the substrate 100 has the P-type conductivity type, the P-type region of the photoelectric conversion region CR may be the substrate 100, and the N-type region of the photoelectric conversion region CR may be a region in which impurities are implanted on the substrate 100 such that the substrate 100 has the N-type conductivity type. For example, the N-type region of the photoelectric conversion region CR may be a region in which impurities including a group 5 element, a group 6 element, or a group 7 element are implanted on the substrate 100. In one or more embodiments, each of the photoelectric conversion regions CR may include a plurality of PN diodes located at different depths. For example, each of the photoelectric conversion regions CR may include a plurality of PN junctions located at different depths.

When light is incident on the photoelectric conversion region CR, an electron-hole pair EHP may be generated within the photoelectric conversion region CR.

Floating diffusion regions FD may be provided in the photodiode regions AR, respectively. The floating diffusion regions FD may be provided in a region adjacent to the first surface 100a of the substrate 100. Each of the floating diffusion regions FD may have the second conductivity type which is opposite to the first conductivity type. Each of the floating diffusion regions FD may include impurities that cause the floating diffusion regions FD to have the second conductivity type. For example, impurities that cause the floating diffusion regions FD to have the second conductivity type may be implanted into the floating diffusion regions FD. The floating diffusion regions FD may be spaced apart from the photoelectric conversion regions CR.

Transfer gate structures TG may be provided in a region adjacent to the first surface 100a. Each of the transfer gate structures TG may be adjacent to a corresponding floating diffusion region FD and a corresponding photoelectric conversion region CR. The transfer gate structures TG may correspond to the gate terminal of the transfer transistor TX described above with reference to FIG. 1.

A portion of each of the transfer gate structures TG may be provided on the first surface 100a of the substrate 100, and another portion of each of the transfer gate structures TG may be inserted into the substrate 100. Each of the transfer gate structures TG including the portions on the first surface 100a of the substrate 100 and the portions inside the substrate 100 may be a vertical transfer gate VTG. Referring to FIG. 4A, each of the transfer gate structures TG may include a transfer gate electrode TGE, a transfer gate insulating layer TGI, and a transfer gate spacer TGP.

Each of the transfer gate electrodes TGE may be adjacent to the corresponding floating diffusion region FD and the corresponding photoelectric conversion region CR. A portion of each of the transfer gate electrodes TGE may be provided on the first surface 100a. Another portion of each of the transfer gate electrodes TGE may be inserted (or extended) into the substrate 100.

Each of the transfer gate insulating layers TGI may be provided between the corresponding transfer gate electrode TGE and the corresponding photodiode region AR. Each of the transfer gate insulating layers TGI may be configured to electrically isolate the corresponding transfer gate electrode TGE and the corresponding photodiode region AR. Each of the transfer gate insulating layers TGI may extend along a surface of the corresponding photodiode region AR.

The transfer gate spacers TGP may be provided on opposite side surfaces of the corresponding transfer gate electrode TGE. Each of the transfer gate spacers TGP may include an insulating material.

Each of the first to fourth pixels PX1, PX2, PX3, and PX4 may include a pixel gate structure PG, a first source/drain region SD1, a second source/drain region SD2, and a shallow trench isolation (STI) pattern. The pixel gate structures PG, the first source/drain regions SD1, and the second source/drain regions SD2 may form transistors used to drive the image sensor. For example, the pixel gate structures PG, the first source/drain regions SD1, and the second source/drain regions SD2 may constitute one of the reset transistor RX, the source follower transistor SF, and the select transistor SEL.

A photodiode isolation trench may be provided. The photodiode isolation trench may penetrate through at least a portion of the substrate 100 from the first surface 100a of the substrate 100. In one or more embodiments, the first region R1 may include the photodiode isolation trench penetrating through the substrate 100.

The photodiode isolation pattern 102 may fill the photodiode isolation trench. In a plan view, the photodiode isolation pattern 102 may surround each of the photoelectric conversion regions CR. The photodiode isolation pattern 102 may surround the first to fourth pixels PX1, PX2, PX3, and PX4. The photodiode isolation pattern 102 may extend in the first direction DR1.

In one or more embodiments, the photodiode isolation pattern 102 may penetrate through the substrate 100. In one or more embodiments, the photodiode isolation pattern 102 may penetrate at least a portion of the substrate 100. As illustrated, the photodiode isolation trench may penetrate through the substrate 100 and thus, the photodiode isolation pattern 102 filling the photodiode isolation trench may penetrate through the substrate 100. Alternatively, the photodiode isolation trench may penetrate through only a portion of the substrate 100, and thus, the photodiode isolation pattern 102 filling the photodiode isolation trench may penetrate through only the portion of the substrate 100. The image sensor may further include a doping isolation region formed in another portion of the substrate 100 and vertically overlapping the photodiode isolation pattern 102.

The photodiode isolation pattern 102 may significantly reduce cross talk, which degrades a signal-to-noise ratio (SNR) caused by charge carrier exchange between mutually adjacent pixels among the first to fourth pixels PX1, PX2, PX3, and PX4.

The photodiode isolation pattern 102 may include at least one of a conductive material and an insulating material. For example, the conductive material may include at least one of doped polysilicon, a metal, a metal silicide, a metal nitride, and a metal-containing material. For example, the insulating material may include at least one of a silicon-based insulating material and a high-κ dielectric. For example, the silicon-based insulating material may include at least one of silicon nitride, silicon oxide, and silicon oxynitride. For example, the high-dielectric material may include a metal oxide including at least one metal selected from the group consisting of hafnium (Hf), zirconium (Zr), aluminum (Al), tantalum (Ta), titanium (Ti), yttrium (Y), or lanthanoid (La).

In one or more embodiments, the photodiode isolation pattern 102 may be disposed in the photodiode isolation trench penetrating through the substrate 100, and a plurality of insulating layers including at least one anti-reflection layer may be disposed between a sidewall of the photodiode isolation trench and the photodiode isolation pattern 102 in a vertical view.

In one or more embodiments, the photodiode isolation trench may further include a shallow isolation pattern between the photodiode isolation pattern 102 and the first surface 100a. The shallow isolation pattern may provide electrical isolation between adjacent elements. In one or more embodiments, the shallow isolation pattern may include an insulating material. For example, the shallow isolation pattern may include at least one of silicon nitride, silicon oxide, and silicon oxynitride.

Vertical conductive lines VCL and horizontal conductive lines HCL may be provided on the first surface 100a. The vertical conductive lines VCL may extend in the first direction DR1. The horizontal conductive lines HCL may extend in, for example, the second direction DR2 or the first direction DR1. The vertical conductive lines VCL and the horizontal conductive lines HCL may include at least one of doped polysilicon and a metal (for example, at least one of copper (Cu), aluminum (Al), molybdenum (Mo), platinum (Pt), titanium (Ti), tantalum (Ta), or tungsten (W)).

A first insulating layer 110 may be provided on the first surface 100a of the substrate 100. The first insulating layer 110 may protect the vertical conductive lines VCL, the horizontal conductive lines HCL, and components provided on the first surface 100a. The first insulating layer 110 may include an insulating material. For example, the first insulating layer 110 may include at least one of silicon oxide, silicon nitride, and silicon oxynitride.

A second insulating layer 120 may be provided on the second surface 100b of the substrate 100. As illustrated in FIG. 4C, the second insulating layer 120 may include a first sub-insulating layer 121, a second sub-insulating layer 122, a third sub-insulating layer 123, and a fourth sub-insulating layer 124, sequentially stacked on the second surface 100b. For example, the first sub-insulating layer 121 may include aluminum oxide. For example, the second sub-insulating layer 122 may include hafnium oxide or titanium oxide. For example, the third sub-insulating layer 123 may include silicon oxide. For example, the fourth sub-insulating layer 124 may include hafnium oxide. In one or more embodiments, the second insulating layer 120 may be configured to suppress reflection of incident light and increase an amount of light incident on the photoelectric conversion regions CR according to thicknesses and refractive indices of the first to fourth sub-insulating layers 121, 122, 123, and 124.

A barrier metal layer BM may be provided on the second insulating layer 120. The barrier metal layer BM may improve adhesion between the fourth sub-insulating layer 124 and a grid 130. For example, the barrier metal layer BM may include at least one of a composite layer of a titanium layer and a titanium nitride layer, or a titanium nitride layer.

The grid 130 may be provided on the pixel array region PAR. For example, the grid 130 may be provided on the barrier metal layer BM of the pixel array region PAR.

In one or more embodiments, the grid 130 may be provided on the pixel array region PAR, and may not be provided on the optical black region OBR. Alternatively, the grid 130 may be provided on the pixel array region PAR and the optical black region OBR.

In the present specification, the grid 130 on the first region R1 of the pixel array region PAR may be referred to as a first grid, the grid 130 on the intermediate region IR of the pixel array region PAR may be referred to as an intermediate region grid, and the grid 130 on the second region R2 of the pixel array region PAR may be referred to as a second grid. When the grid 130 is provided on the optical black region OBR, the grid 130 on the optical black region OBR may be referred to as a third grid.

As illustrated in FIGS. 3A, 3B, and 5A to 7B, the grid 130 may have a layer structure on each of the first region R1, the intermediate region IR, and the second region R2. For example, the grid 130 may have a single-layer structure or a multilayer structure on each of the first region R1, the intermediate region IR, and the second region R2. The third region R3 may include layers including the same materials as materials forming the first grid, the intermediate region grid, and the second grid.

Alternatively, the grid 130 may have a layer structure on each of the first region R1, the intermediate region IR, and the second and third regions R2 and R3. The grid 130 may have a single-layer structure or a multilayer structure even on the third region R3.

The first grid may include N layers stacked in the first direction DR1. The intermediate region grid may include K layers stacked in the first direction DR1. The second grid may include M layers stacked in the first direction DR1. The third region R3 may include layers composed of the same materials as the materials constituting the first grid, the intermediate region grid, and the second grid. Each of N, K, and M may be an integer equal to or greater than 1. N, K, and M may be different integers. For example, M may be greater than N. For example, M may be greater than K. For example, K may be greater than N.

Alternatively, when the grid 130 is provided on the optical black region OBR, the third grid may include L layers stacked in the first direction DR1. Each of N, K, M, and L may be an integer greater than or equal to 1. M may be an integer greater than N, and L may be an integer greater than N. In one or more embodiments, M and L may be integers greater than or equal to 2. In one or more embodiments, M may be an integer equal to L.

In one or more embodiments, the grid 130 may have a single-layer structure in the first region R1, may include two layers in the intermediate region IR, and may include three layers in the second region R2. In addition, the grid 130 may not have a layer structure in the third region R3.

Alternatively, when the grid 130 is provided on the optical black region OBR, the grid 130 may also have a layer structure in the third region R3. The grid 130 may have three layers in the third region R3, but embodiments are not limited thereto.

Alternatively, the grid 130 may have four or more layers in the first region R1, the intermediate region IR, and the second and third regions R2 and R3.

However, embodiments are not limited thereto. The pixel array region PAR may include a plurality of regions, and the grid 130 may have a single-layer structure or a multilayer structure in each of the plurality of regions. In one or more embodiments, the number of layers of the grid 130 may increase in a direction from a center region to an outermost region among the plurality of regions. Alternatively, the grid 130 may have non-regular numbers of layers in the plurality of regions.

Hereinafter, for ease of description, the grid 130 having a single-layer structure in the first region R1, two layers in the intermediate region IR, and three layers in the second region R2 may be described.

In the present specification, the grid 130 on the first region R1 of the pixel array region PAR may be referred to as the first grid, the grid 130 on the intermediate region IR of the pixel array region PAR may be referred to as the intermediate region grid, and the grid 130 on the second region R2 of the pixel array region PAR may be referred to as the second grid. When the grid 130 is provided on the optical black region OBR, the grid 130 on the optical black region OBR may be referred to as the third grid.

A height of the first grid in the first direction DR1 may be different from a height of the second grid in the first direction DR1. In one or more embodiments, the height of the first grid in the first direction DR1, a height of the intermediate region grid in the first direction DR1, and the height of the second grid in the first direction DR1 may be different from each other. For example, the height of the first grid in the first direction DR1 may be smaller than the height of the second grid in the first direction DR1. In one or more embodiments, when the grid 130 is provided on the optical black region OBR, the height of the first grid in the first direction DR1, the height of the intermediate region grid in the first direction DR1, the height of the second grid in the first direction DR1, and a height of the third grid in the first direction DR1 may be different from each other. For example, the height of the first grid in the first direction DR1 may be smaller than the height of the second grid in the first direction DR1, and the height of the first grid in the first direction DR1 may be smaller than the height of the third grid in the first direction DR1.

As illustrated in FIGS. 3A and 3B, the N layers of the first grid may include a first sub-grid pattern 132. In one or more embodiments, N may be an integer equal to 1. The height of the first grid may be a height of the first sub-grid pattern 132 in the first direction DR1. The first sub-grid pattern 132 may include a material having a low refractive index. For example, a refractive index of the first sub-grid pattern 132 may be about 1.5 or less. For example, the first sub-grid pattern 132 may include at least one of tetraethoxysilane (TEOS), phenyltriethoxysilane (PTEOS), or a porous low-κ dielectric.

As illustrated in FIGS. 5A and 5B, the K layers of the intermediate region grid may include the first sub-grid pattern 132 and a second sub-grid pattern 134. The second sub-grid pattern 134 may be provided between the first sub-grid pattern 132 and the second surface 100b of the substrate 100. For example, the second sub-grid pattern 134 may be provided between the first sub-grid pattern 132 and a photodiode of the intermediate region IR. A height of the first sub-grid pattern 132 in the first direction DR1 may be greater than a height of the second sub-grid pattern 134 in the first direction DR1. In one or more embodiments, the height of the first sub-grid pattern 132 in the first direction DR1 may be about 3 times or more greater than the height of the second sub-grid pattern 134 in the first direction DR1. Alternatively, the height of the first sub-grid pattern 132 in the first direction DR1 may be about 2 times or more greater than the height of the second sub-grid pattern 134 in the first direction DR1. In one or more embodiments, K may be an integer equal to 2. The height of the intermediate region grid may be a sum of the height of the first sub-grid pattern 132 in the first direction DR1 and the height of the second sub-grid pattern 134 in the first direction DR1. Accordingly, the height of the intermediate region grid may be greater than the height of the first grid. The second sub-grid pattern 134 may include a material having a low refractive index. For example, a refractive index of the second sub-grid pattern 134 may be about 1.5 or less. In one or more embodiments, the second sub-grid pattern 134 may include a material different from that of the first sub-grid pattern 132. For example, the second sub-grid pattern 134 may include a metal (for example, at least one of tungsten (W) and titanium nitride (TiN)).

As illustrated in FIGS. 6A and 6B, the M layers of the second grid may include the first sub-grid pattern 132, the second sub-grid pattern 134, and a third sub-grid pattern 136. The second sub-grid pattern 134 may be provided between the first sub-grid pattern 132 and the second surface 100b of the substrate 100. For example, the second sub-grid pattern 134 may be provided between the first sub-grid pattern 132 and a photodiode of the second region R2. The third sub-grid pattern 136 may be provided between the first sub-grid pattern 132 and the second sub-grid pattern 134. The height of the first sub-grid pattern 132 in the first direction DR1 may be greater than the height of the second sub-grid pattern 134 in the first direction DR1. The height of the first sub-grid pattern 132 in the first direction DR1 may be greater than a height of the third sub-grid pattern 136. In one or more embodiments, the height of the first sub-grid pattern 132 in the first direction DR1 may be about 3 times or more greater than the height of the second sub-grid pattern 134 in the first direction DR1. Alternatively, the height of the first sub-grid pattern 132 in the first direction DR1 may be about 2 times or more greater than the height of the second sub-grid pattern 134 in the first direction DR1. In one or more embodiments, M may be an integer of 3. The height of the second grid may be a sum of the height of the first sub-grid pattern 132 in the first direction DR1, the height of the second sub-grid pattern 134 in the first direction DR1, and a height of the third sub-grid pattern 136 in the first direction DR1. Accordingly, the height of the second grid may be greater than the height of the first grid and the height of the intermediate region grid. The third sub-grid pattern 136 may include a material having a low refractive index. For example, a refractive index of the third sub-grid pattern 136 may be about 1.5 or less. In one or more embodiments, the third sub-grid pattern 136 may include a material different from that of the first sub-grid pattern 132. The third sub-grid pattern 136 may include substantially the same material as the second sub-grid pattern 134. For example, the third sub-grid pattern 136 may include a metal (for example, at least one of tungsten (W) and titanium nitride (TiN)).

However, embodiments are not limited thereto. The first to third sub-grid patterns 132, 134, and 136 may include substantially the same material. For example, the first to third sub-grid patterns 132, 134, and 136 may include at least one of tetraethoxysilane (TEOS), phenyltriethoxysilane (PTEOS), and a porous low-κ dielectric.

As illustrated in FIGS. 7A and 7B, a first peripheral layer ML1 and a second peripheral layer ML2 may be provided in the third region R3. The first peripheral layer ML1 and the second peripheral layer ML2 may be stacked along the first direction DR1. The first peripheral layer ML1 may include the same material as the second sub-grid pattern 134, and a height of the first peripheral layer ML1 in the first direction DR1 may be substantially the same as the height of the second sub-grid pattern 134 in the first direction DR1. The second peripheral layer ML2 may include the same material as the third sub-grid pattern 136, and a height of the second peripheral layer ML2 in the first direction DR1 may be substantially the same as the height of the third sub-grid pattern 136 in the first direction DR1. For example, refractive indices of the first and second peripheral layers ML1 and ML2 may be about 1.5 or less. In one or more embodiments, each of the first and second peripheral layers ML1 and ML2 may include a metal (for example, at least one of tungsten (W) and titanium nitride (TiN)). Alternatively, each of the first and second peripheral layers ML1 and ML2 may include at least one of tetraethoxysilane (TEOS), phenyltriethoxysilane (PTEOS), and a porous low-κ dielectric.

An upper layer UL may be provided on the second peripheral layer ML2 of the third region R3. In one or more embodiments, the upper layer UL may have a multilayer structure. For example, the upper layer UL may include a light blocking layer and a resin layer.

In contrast to the illustrated embodiment, in one or more embodiments, when the grid 130 is provided on the optical black region OBR, the L layers of the third grid may include a first sub-grid pattern 132, a second sub-grid pattern 134, and a third sub-grid pattern 136. The first to third sub-grids 132, 134, and 136 may be the same as the first to third sub-grids 132, 134, and 136 described above with reference to FIGS. 6A and 6B. In one or more embodiments, L may be an integer equal to 3. A height of the third grid may be a sum of the height of the first sub-grid pattern 132 in the first direction DR1, the height of the second sub-grid pattern 134 in the first direction DR1, and the height of the third sub-grid pattern 136 in the first direction DR1.

The grid 130 may have a lattice shape defining color filter regions CFR. For example, the grid 130 may extend along an edge of each of the first to fourth pixels PX1, PX2, PX3, and PX4. Accordingly, the grid 130 may be provided along an edge of the first to fourth pixel groups PXG1, PXG2, PXG3, PXG4. In a plan view, the grid 130 may be disposed in a center area surrounded by the first to fourth pixel groups PXG1, PXG2, PXG3, and PXG4.

In one or more embodiments, each of the first to fourth pixel groups PXG1, PXG2, PXG3, and PXG4 may include four photodiodes arranged in a 2×2 matrix in a plan view. In the present specification, four photodiodes of the first pixel group PXG1 of the first region R1 may be referred to as first-four photodiodes, four photodiodes of the second pixel group PXG2 of the first region R1 may be referred to as second-four photodiodes, four photodiodes of the third pixel group PXG3 of the first region R1 may be referred to as third-four photodiodes, and four photodiodes of the fourth pixel group PXG4 of the first region R1 may be referred to as fourth-four photodiodes. In a plan view, the first grid may not be disposed in a center portion surrounded by the first-four photodiodes. In one or more embodiments, in a plan view, the first grid may not be disposed in a center portion surrounded by the first-four photodiodes, may not be disposed in a center portion surrounded by the second-four photodiodes, may not be disposed in a center portion surrounded by the third-four photodiodes, and may not be disposed in a center portion surrounded by the fourth-four photodiodes.

A plurality of color filters CF may be provided on the second surface 100b of the substrate 100. For example, the plurality of color filters CF may be provided on color filter regions CFR. Accordingly, the first grid may be provided on the first region R1 and may be provided between the color filters CF on the first region R1 among the plurality of color filters CF. The intermediate region grid may be provided on the intermediate region IR and may be provided between the color filters CF on the intermediate region IR among the plurality of color filters CF. The second grid may be provided on the second region R2 and may be provided between the color filters CF on the second region R2 among the plurality of color filters CF.

In one or more embodiments, when each of the first to fourth pixel groups PXG1, PXG2, PXG3, and PXG4 includes four photodiodes arranged in a 2×2 matrix in a plan view, the first pixel group PXG1 of the first region R1 may include the first-four photodiodes arranged in a 2×2 matrix in a plan view and a first first-region color filter on the first-four photodiodes. The second pixel group PXG2 of the first region R1 may include the second-four photodiodes arranged in a 2×2 matrix in a plan view and a second first-region color filter on the second-four photodiodes. The third pixel group PXG3 of the first region R1 may include the third-four photodiodes arranged in a 2×2 matrix in a plan view and a third first-region color filter on the third-four photodiodes. The fourth pixel group PXG4 of the first region R1 may include the fourth-four photodiodes arranged in a 2×2 matrix in a plan view and a fourth first-region color filter on the fourth-four photodiodes.

Incident light passing through the color filters CF may be incident on the photodiode regions AR, respectively corresponding to the color filter regions CFR corresponding to the color filters CF.

A center axis of each of the photodiode regions AR of the first region R1 may be substantially aligned with a center axis of a corresponding color filter region CFR. Each of the center axes of the photodiode regions AR may pass through a center of the photodiode region AR and may extend in the first direction DR1. Each of the center axes of the color filter regions CFR may pass through a center of the color filter region CFR and may extend in the first direction DR1.

A center axis of each of the photodiode regions AR of the intermediate region IR may not be aligned with the center axis of the corresponding color filter region CFR. For example, the center axis of each of the photodiode regions AR of the intermediate region IR may be offset from the center axis of the corresponding color filter region CFR. A distance between the center axis of each of the photodiode regions AR of the intermediate region IR and the center axis of the corresponding color filter region CFR may be a first separation distance.

In one or more embodiments, referring to FIG. 1, each of the center axes of the photodiode regions AR on the intermediate region IR arranged in the third direction DR3 with respect to the first region R1 may be spaced apart from the center axis of the corresponding color filter region CFR in the third direction DR3. Each of the center axes of the photodiode regions AR on the intermediate region IR arranged in the second direction DR2 with respect to the first region R1 may be spaced apart from the center axis of the corresponding color filter region CFR in the second direction DR2. Each of the center axes of the photodiode regions AR on the intermediate region IR arranged in a fourth direction DR4 with respect to the first region R1 may be spaced apart from the center axis of the corresponding color filter region CFR in the fourth direction DR4. Each of the center axes of the photodiode regions AR on the intermediate region IR arranged in a fifth direction DR5 with respect to the first region R1 may be spaced apart from the center axis of the corresponding color filter region CFR in the fifth direction DR5.

A center axis of each of the photodiode regions AR of the second region R2 may not be aligned with the center axis of the corresponding color filter region CFR. For example, the center axis of each of the photodiode regions AR of the second region R2 may be offset from the center axis of the corresponding color filter region CFR. A distance between the center axis of each of the photodiode regions AR of the second region R2 and the center axis of the corresponding color filter region CFR may be a second separation distance. The second separation distance may be greater than the first separation distance.

In one or more embodiments, referring to FIG. 1, each of the center axes of the photodiode regions AR on the second region R2 arranged in the third direction DR3 with respect to the intermediate region IR may be spaced apart from the center axis of the corresponding color filter region CFR in the third direction DR3. Each of the center axes of the photodiode regions AR on the second region R2 arranged in the second direction DR2 with respect to the intermediate region IR may be spaced apart from the center axis of the corresponding color filter region CFR in the second direction DR2. Each of the center axes of the photodiode regions AR on the second region R2 arranged in the fourth direction DR4 with respect to the intermediate region IR may be spaced apart from the center axis of the corresponding color filter region CFR in the fourth direction DR4. Each of the center axes of the photodiode regions AR on the second region R2 arranged in the fifth direction DR5 with respect to the intermediate region IR may be spaced apart from the center axis of the corresponding color filter region CFR in the fifth direction DR5.

The color filters CF may be provided on the barrier metal layer BM and may be provided on each of the color filter regions CFR. Each of the color filters CF may be surrounded by the grid 130.

In one or more embodiments, a height of the color filters CF in the first direction DR1 in the first region R1 may be greater than the height of the first grid in the first direction DR1. Accordingly, the color filters CF in the first region R1 may cover an upper surface of the first grid. A height of the color filters CF in the first direction DR1 in the intermediate region IR may be smaller than the height of the intermediate region grid in the first direction DR1. Accordingly, the intermediate region grid in the intermediate region IR may protrude upwardly of an upper surface of the color filters CF. A height of the color filters CF in the first direction DR1 in the second region R2 may be smaller than the height of the second grid in the first direction DR1. Accordingly, the second grid in the second region R2 may protrude upwardly of an upper surface of the color filters CF.

In one or more embodiments, the color filters CF may be provided in the first to fourth pixels PX1, PX2, PX3, and PX4, respectively. For example, the color filter CF on the first pixel PX1 may be a red filter, the color filter CF on the second pixel PX2 may be a green filter, the color filter CF on the third pixel PX3 may be a green filter, and the color filter CF on the fourth pixel PX4 may be a blue filter. Alternatively, the color filter CF on the first pixel PX1 may be a cyan filter, the color filter CF on the second pixel PX2 may be a yellow filter, the color filter CF on the third pixel PX3 may be a green filter, and the color filter CF on the fourth pixel PX4 may be a magenta filter.

A lens layer LL may be provided on the second surface 100b of the substrate 100. Accordingly, the second surface 100b of the substrate 100 may be configured to receive light. The lens layer LL may include lenses LS.

In one or more embodiments, each of the lenses LS may be a microlens. The first region R1, the intermediate region IR, and the second region R2 may include microlenses. The microlenses on the first region R1 may be referred to as first microlenses, the microlenses on the intermediate region IR may be referred to as intermediate region microlenses, and the microlenses on the second region R2 may be referred to as second microlenses.

In a vertical view, the first grid may not be disposed at a center of each of the first microlenses. In a vertical view, the second grid may not be disposed at a center of the second microlenses. For example, when one of the first microlenses covers the first to fourth pixels PX1, PX2, PX3, and PX4 of the first pixel group PXG1, a center of the one first microlens may vertically overlap a center of the first to fourth pixels PX1, PX2, PX3, and PX4. The first grid may not be disposed at the center of the one first microlens.

In the present specification, the second microlenses of the second region R2 may be referred to as first second-region microlenses. In addition, a color filter provided between the first second-region photodiode and the first second-region microlens may be referred to as a first second-region color filter. A distance in the first direction DR1 from the second surface 100b of the substrate 100 to the upper surface of the second grid may be greater than a distance from the second surface 100b of the substrate 100 to an upper surface of the first second-region color filter.

The second region R2 may further include the second second-region photodiode. The first second-region microlens may be disposed on the first second-region photodiode and the second second-region photodiode. However, embodiments are not limited thereto. Each of the microlenses may be disposed on a single photodiode or a plurality of photodiodes based on the efficiency and purpose of the image sensor.

Each of the lenses LS may be configured to condense incident light onto a corresponding photoelectric conversion region CR. The lens LS may include a resin-based material. For example, the lens LS may include at least one of a styrene-based resin, an acrylic-based resin, a styrene-acrylic copolymer-based resin, or a siloxane-based resin.

A center axis of each of the color filter regions CFR of the first region R1 may be substantially aligned with a center axis of the corresponding lens LS. Each of the center axes of the lenses LS may pass through a center of the lens LS and may extend in the first direction DR1.

A center axis of each of the color filter regions CFR of the intermediate region IR may not be aligned with the center axis of the corresponding lens LS. That is, the center axis of each of the color filter regions CFR of the intermediate region IR may be offset from the center axis of the corresponding lens LS. The center axis of each of the color filter regions CFR of the intermediate region IR and the center axis of the corresponding lens LS may have a third separation distance.

In one or more embodiments, referring to FIG. 1, each of the center axes of the color filter regions CFR on the intermediate region IR arranged in the third direction DR3 with respect to the first region R1 may be spaced apart from the center axis of the corresponding lens LS along the third direction DR3. Each of the center axes of the color filter regions CFR on the intermediate region IR arranged in the second direction DR2 with respect to the first region R1 may be spaced apart from the center axis of the corresponding lens LS in the second direction DR2. Each of the center axes of the color filter regions CFR on the intermediate region IR arranged in the fourth direction DR4 with respect to the first region R1 may be spaced apart from the center axis of the corresponding lens LS in the fourth direction DR4. Each of the center axes of the color filter regions CFR on the intermediate region IR arranged in the fifth direction DR5 with respect to the first region R1 may be spaced apart from the center axis of the corresponding lens LS in the fifth direction DR5.

A center axis of each of the color filter regions CFR of the second region R2 may not be aligned with the center axis of the corresponding lens LS. For example, the center axis of each of the color filter regions CFR of the second region R2 may be offset from the center axis of the corresponding lens LS. A distance between the center axis of each of the color filter regions CFR of the second region R2 and the center axis of the corresponding lens LS may be a fourth separation distance. The fourth separation distance may be greater than the third separation distance.

In one or more embodiments, referring to FIG. 1, each of the center axes of the color filter regions CFR on the second region R2 arranged in the third direction DR3 with respect to the intermediate region IR may be spaced apart from the center axis of the corresponding lens LS in the third direction DR3. Each of the center axes of the color filter regions CFR on the second region R2 arranged in the second direction DR2 with respect to the intermediate region IR may be spaced apart from the center axis of the corresponding lens LS in the second direction DR2. Each of the center axes of the color filter regions CFR on the second region R2 arranged in the fourth direction DR4 with respect to the intermediate region IR may be spaced apart from the center axis of the corresponding lens LS in the fourth direction DR4. Each of the center axes of the color filter regions CFR on the second region R2 arranged in the fifth direction DR5 with respect to the intermediate region IR may be spaced apart from the center axis of the corresponding lens LS in the fifth direction DR5.

Incident light may be incident on the pixel array region PAR at a larger chief ray angle CRA in a direction toward an edge of the pixel array region PAR, and the incident light may be incident on the pixel array region PAR at a relatively smaller chief ray angle in a direction toward the center of the pixel array region PAR. The incident light may be incident on the lenses LS, and then may reach the photoelectric conversion region CR of the photodiode region AR corresponding to each of the lenses LS.

The incident light at the edge of the pixel array region PAR may be obliquely incident due to the relatively large chief ray angle, and thus, may be incident towards the grid 130. For example, optical cross talk may occur due to the large chief ray angle of the incident light.

The image sensor according to the above-described embodiment may include the grid 130 having different heights based on the likelihood of occurrence of optical cross talk. For example, the first region R1 may have the lowest likelihood of occurrence of optical cross talk, and the first grid of the first region R1 may have the lowest height. The second region R2, for example, the closest region to the optical black region OBR may have the highest likelihood of occurrence of optical cross talk, and the second grid of the second region R2 may have a maximum height. As a result, optical characteristics of the image sensor may be improved.

In a method of manufacturing the image sensor including the grid 130, a first preliminary grid layer may be formed on the barrier metal layer BM. The first preliminary grid layer may be formed on the pixel array region PAR and the optical black region OBR. In one or more embodiments, the first preliminary grid layer may be formed by a deposition process.

The first preliminary grid layer may be patterned to form the second sub-grid pattern 134. The second sub-grid pattern 134 may be formed on the intermediate region IR and the second region R2. The first preliminary grid layer on the first region R1 may be removed. For example, the first preliminary grid layer on the first region R1 may be completely removed. The first preliminary grid layer on the third region R3 may remain without being patterned. The remaining first preliminary grid layer of the third region R3 may be the first peripheral layer ML1. In one or more embodiments, when the grid 130 is provided on the optical black region OBR, the first preliminary grid layer of the third region R3 may be patterned to form the second sub-grid pattern 134.

Then, a second preliminary grid layer may be formed to cover the second sub-grid pattern 134. The second preliminary grid layer may be formed on the pixel array region PAR and the optical black region OBR. The second preliminary grid layer may be patterned to form the third sub-grid pattern 136 on the second sub-grid pattern 134 on the second region R2. The preliminary second grid layer on the first region R1 and the intermediate region IR may be removed. For example, the preliminary second grid layer on the first region R1 and the intermediate region IR may be completely removed. The preliminary second grid layer of the third region R3 may remain without being patterned. The remaining preliminary second grid layer of the third region R3 may be the second peripheral layer ML2. In one or more embodiments, when the grid 130 is provided on the optical black region OBR, the second preliminary grid layer of the third region R3 may be patterned to form the third sub-grid pattern 136 on the third region R3. The third sub-grid pattern 136 of the third region R3 may be formed on the second sub-grid pattern 134.

Then, a base grid layer may be formed on the pixel array region PAR and the optical black region OBR. The base grid layer may be patterned to form the first sub-grid pattern 132. The first sub-grid pattern 132 on the first region R1 may be formed on the barrier metal layer BM. For example, the first grid of the first region R1 may be formed on the barrier metal layer BM. The first sub-grid pattern 132 on the intermediate region IR may be formed on the second sub-grid pattern 134. The first sub-grid pattern 132 on the second region R2 may be formed on the third sub-grid pattern 136.

As set forth above, according to embodiments, an image sensor having improved optical characteristics may be provided. However, embodiments are not limited thereto

While various embodiments have been shown and described above, it will be apparent to those skilled in the art that modifications and variations could be made without departing from the scope of the present inventive concept as defined by the appended claims.

What is claimed is:

1. An image sensor comprising:
a substrate comprising a first surface, a second surface opposing the first surface, a first region located at a center area of the substrate, an optical black region, and a second region between the first region and the optical black region in a plan view;
a plurality of color filters on the second surface of the substrate;
a first grid between the plurality of color filters on the first region; and
a second grid between the plurality of color filters on the second region,
wherein the first grid comprises N layers stacked in a first direction perpendicular to the second surface of the substrate,
wherein the second grid comprises M layers stacked in the first direction,
wherein a height of the first gird in the first direction is different from a height of the second grid in the first direction,
wherein the N and M are integers equal to or greater than 1,
wherein the N is different from the M, and
wherein the image sensor is configured to receive light from the second surface of the substrate.

2. The image sensor of claim 1, wherein the M is greater than the N.

3. The image sensor of claim 2, wherein the second region comprising:
a first second-region photodiode;
a first second-region microlens; and
a first second-region color filter between the first second-region photodiode and the first second-region microlens,
wherein a distance from the second surface of the substrate to a top surface of the second grid in the first direction is greater than a distance from the second surface of the substrate to a top surface of the first second-region color filter in the first direction.

4. The image sensor of claim 3, wherein the second region further comprising:
a second second-region photodiode,
wherein the first second-region microlens is disposed on the first second-region photodiode and the second second-region photodiode.

5. The image sensor of claim 4, wherein the M layers comprising:
a first sub-grid pattern; and
a second sub-grid pattern between the first sub-grid pattern and the first second-region photodiode,
wherein a height of the first sub-grid pattern in the first direction is greater than a height of the second sub-grid pattern in the first direction.

6. The image sensor of claim 4, wherein the first region comprising:
a first pixel group comprising a first-four photodiodes arranged in a 2×2 matrix in a plan view, and a first first-region color filter on the first-four photodiodes;
a second pixel group comprising a second-four photodiodes arranged in the 2×2 matrix in the plan view, and a second first-region color filter on the second-four photodiodes;
a third pixel group comprising a third-four photodiodes arranged in the 2×2 matrix in the plan view, and a third-region color filter on the third-four photodiodes; and
a fourth pixel group comprising fourth-four photodiodes arranged in the 2×2 matrix in the plan view, and a fourth first-region color filter on the fourth-four photodiodes.

7. The image sensor of claim 6, wherein the first grid is disposed at a center area surrounded by the first to fourth pixel groups in the plan view.

8. The image sensor of claim 7, wherein the first gird is not disposed at a center area surrounded by the first-four photodiodes in the plan view.

9. The image sensor of claim 6, wherein the height of a first sub-grid pattern in the first direction is equal to or more than three times greater than the height of a second sub-grid pattern in the first direction.

10. The image sensor of claim 9, wherein the optical black region comprising:
a third grid on the second surface of the substrate,
wherein the height of the first gird in the first direction is smaller than a height of the third grid in the first direction.

11. The image sensor of claim 10, wherein the third grid comprising:
L layers, wherein the L is an integer equal to or greater than 2.

12. The image sensor of claim 6, wherein the first region further comprising:
a photodiode isolation trench penetrating the substrate.

13. An image sensor comprising:
a substrate comprising a first surface, a second surface opposing the first surface, a first region located at a center area of the substrate, an optical black region, and a second region between the first region and the optical black region in a plan view;
a plurality of color filters on the second surface of the substrate;
a first grid between the plurality of color filters on the first region;
a second grid between the plurality of color filters on the second region; and
a third grid on the second surface of the substrate on the optical black region,
wherein the first grid comprises N layers stacked in a first direction perpendicular to the second surface of the substrate,
wherein the second grid comprises M layers stacked in the first direction,
wherein the third grid comprises L layers stacked in the first direction,
wherein a height of the first gird in the first direction is smaller than a height of the second grid in the first direction,
wherein the height of the first gird in the first direction is smaller than and a height of the third grid in the first direction,
wherein the N, M, and L are integers equal to or greater than 1,
wherein the M is greater than the N,
wherein the L is greater than the N, and
wherein the image sensor is configured to receive light from the second surface of the substrate.

14. The image sensor of claim 13, wherein each of the M and L is equal to or greater than 2.

15. The image sensor of claim 13, wherein the M layers comprises a metal material.

16. The image sensor of claim 15, wherein the M layers comprising:
a first sub-grid pattern; and
a second sub-grid pattern between the first sub-grid pattern and a photodiode,
wherein a height of the first sub-grid pattern in the first direction is greater than a height of the second sub-grid pattern in the first direction.

17. The image sensor of claim 16, wherein the height of the first sub-grid pattern in the first direction is equal to or more than twice greater than the height of the second sub-grid pattern in the first direction.

18. The image sensor of claim 17, wherein the first region further comprising:
a photodiode isolation trench penetrating the substrate.

19. The image sensor of claim 14, wherein the M is equal to the L.

20. An image sensor comprising:
a substrate comprising a first surface, a second surface opposing the first surface, a first region located at a center area of the substrate, an optical black region, and a second region between the first region and the optical black region in a plan view;
a plurality of color filters on the second surface of the substrate;
a first grid between the plurality of color filters on the first region;
a second grid between the plurality of color filters on the second region,
a first microlens on a first photodiode and a second photodiode on the first region; and
a second microlens on a third photodiode and a fourth photodiode on the second region,
wherein the first grid comprises N layers stacked in a first direction perpendicular to the second surface of the substrate,
wherein the second grid comprises M layers stacked in the first direction,
wherein a height of the first gird in the first direction is smaller than a height of the second grid in the first direction,
wherein the N and M are integers equal to or greater than 1,
wherein the N is different from the M,
wherein the first gird is not disposed at a center of the first microlens in a vertical view,
wherein the second gird is not disposed at a center of the second microlens in a vertical view, and
wherein the image sensor is configured to receive light from the second surface of the substrate.
